(19) United States
(12) Patent Application Publication
(10) Pub. No.: US 2010/0047475 A1
(43) Pub. Date: Feb. 25, 2010

(54) Coated filaments and their manufacture

(76) Inventors: Ray Paul Durman, Wokingham (GB); Robert Alan Shatwell, Farnham (GB); Stephen John Kyle-Henney, Leatherhead (GB); Renny Neil Moss, Ashtead (GB); Robert Slightam, Woking (GB)

Correspondence Address: Kenneth Watov, Esq.;WATOV & KIPNES, P.C., P.O.Box 247, Princeton Junction, NJ, 08550, US

(21) Appl. No.: 12/231,090

(22) Filed: Aug. 29, 2008

(30) Foreign Application Priority Data
Aug. 22, 2008 (GB) 0815296.9

(51) Int. Cl. C23C 16/507; C23C 14/34

(52) U.S. Cl. 427/587; 118/723 R; 204/192.12

(57) ABSTRACT

A coating is formed by chemical vapour deposition an electrically heated filament which is passed through an end plate into a deposition chamber and leaves the deposition chamber through a similar end plate. The filament slides through an entrance passage into a first electrode chamber, around part of a wheel electrode into the deposition chamber. The passage of the filament around the wheel electrode provides adequate direct electrical contact. The end plate operates in exactly the same manner. As no mercury or a low-melting point eutectic alloy is used, no contaminants associated therewith are produced and the resultant coated filament is free of such contaminants.

### RELATED APPLICATION

The present application is related to Ser. No. ______ (Attorney Docket No. 827.1.030) for “Coated Filaments And Their Manufacture,” filed on Aug. 29, 2008. Also this application claims foreign priority benefits under 35 U.S.C. 119 of prior United Kingdom Application No. 0815296.9, filed on Aug. 22, 2008, the entire disclosure of which is incorporated herein by reference.

### FIELD OF THE INVENTION

This invention relates to coated filaments, and to an apparatus and a method for their formation.

### BACKGROUND TO THE INVENTION

It is well known to deposit a coating on an electrically conductive filament using chemical vapour deposition techniques. Typically the electrically conductive filament is passed continuously through a deposition chamber containing an appropriate gas or gases whilst the filament is heated by the passage of an electrical current, and the gas or gases deposit a coating on the hot filament. This is a process of “chemical vapour deposition” or CVD and essentially requires the provision of gas seals around the electrical contacts to the filament at both ends of the deposition chamber.

EP 0 396 333 teaches that silicon carbide may be coated on a tungsten filament which passes through electrodes at the ends of a deposition chamber, the entrance electrode is a pool of mercury and the exit electrode is a mercury/indium amalgam. The pool of mercury and the mercury/indium amalgam both serve the dual function of providing a gas seal around and an electrical contact to the tungsten filament.

U.S. Pat. No. 3,622,369 and U.S. Pat. No. 4,127,659 both describe similar processes for depositing silicon carbide on a filament.

EP 0 396 332 teaches that an exit electrode for a ceramically coated filament should, instead of using mercury, utilise a liquid metal mixture of mercury/indium or mercury/cadmium amalgam or a gallium/indium mixture.

EP 0 450 760 teaches that carbon may be coated on a filament which comprises a tungsten core coated with silicon carbide and is passed through mercury electrodes at the ends of a deposition chamber.

EP 0 598 491 teaches that a layer of titanium carbide can be deposited on a tungsten core as an intermediate layer, an outer layer being of silicon carbide. Again, mercury electrodes are used at the ends of the deposition chamber.

These CVD techniques for producing coated filaments can be applied to different electrically conductive core materials capable of being heated electrically by the direct application of electrical current, or by induction, and to a range of coatings provided by an appropriate selection of reactive gas or gases.

### SUMMARY OF THE INVENTION

We have found that these techniques for producing coated filaments inevitably result in mercury contamination of the coated filament. Such contamination occurs by the physical contact of the filament with liquid mercury forming the entry electrode, and by physical contact of the coating with liquid mercury forming the exit electrode. Further contamination occurs due to the production of mercury vapour by both of the electrodes. Some of this mercury vapour adheres to the filament as it approaches the deposition chamber and some adheres to the coating as the coated filament leaves the exit electrode. Mercury vapour also enters the deposition chamber and mingles with the gas or gases that produce the coating with the result that mercury may be incorporated within the coating. Mercury vapour additionally issues from the vicinity of both mercury pools and constitutes a potential health hazard. Similar problems occur with the use of liquid metal as the electrodes, for instance mercury/indium, mercury/cadmium or gallium/indium, in which case the contaminants would of course be mercury, indium, cadmium, and/or gallium.

As a result, the coated filament is compromised by contaminants which are on, within or under the coating. To some extent surface contaminants can be cleaned off the surface of the coating, but contaminants within or under the coating cannot readily be removed.

According to one aspect of the invention a filament coating apparatus comprises a deposition chamber in which a coating is to be applied to the filament, a first electrode structure having an entrance passage permitting the filament to slide into the electrode chamber and an exit passage permitting the filament to slide from the electrode chamber into the deposition chamber, a second electrode structure having an entrance passage permitting the coated filament to slide out of the deposition chamber into the second electrode chamber and an exit passage permitting the coated filament to slide out of the second electrode chamber, the first electrode chamber housing a first roller electrode means providing direct electrical contact with the filament, and the second electrode chamber housing a second roller electrode means providing direct electrical contact with the coated filament. In this manner the filament can be coated without the use of liquid metal as the electrode and will not be contaminated by mercury, indium, cadmium or gallium.

Preferably, sealing means is provided to inhibit the escape of gas from the deposition chamber into either electrode chamber.

Each electrode chamber may be provided with a gas inlet to supply gas at a pressure greater than an operational pressure within the deposition chamber. Alternatively, each electrode chamber may be provided with a gas outlet to reduce its internal pressure to below atmospheric pressure. Each sealing means may comprise a gas outlet to remove gas escaping into its electrode chamber from the deposition chamber.

The first roller electrode means may comprise an electrode wheel positioned relative to its entrance passage and its exit passage to ensure adequate direct electrical contact with the filament. Similarly, the second roller electrode means may comprise an electrode wheel positioned relative to its entrance passage and its exit passage to ensure adequate direct electrical contact with the coated filament. Preferably the entrance passage to the first electrode and the exit passage from the second electrode are both horizontal.

Alternatively, at least one of the roller electrode means may comprise at least two opposed wheels positioned to press against opposite sides of the filament or the coated filament to ensure adequate direct electrical contact, and at least one of the opposed wheels is an electrode. In this event the roller electrode means preferably comprises three wheels positioned such that two of them press against one side of the filament or the coated filament and the third wheel is pressed against the opposite side of the filament or coated filament between the first and second wheels. Preferably one of the wheels of the roller electrode means is positioned to guide the filament or coated filament into alignment with the appropriate exit passage.

Alternatively, at least one of the roller electrode means may comprise a roller electrode mounted for rotation about an axis that is oblique to a line between the associated entrance passage and the associated exit passage whereby the filament or coated filament can be wound at least once around the roller whilst passing from the entrance passage to the exit passage to ensure adequate direct electrical contact. The roller electrode may have a spiral surface for engaging the filament.

The first roller electrode and the second roller electrode may form an electrical circuit for heating the filament to cause chemical vapour deposition of the coating from a gas or gases within the deposition chamber. Alternatively, the first roller electrode and the second roller electrode may form an electrostatic circuit to produce an electrostatic charge to cause physical vapour deposition of the coating from material within the deposition chamber.

According to another aspect of the invention, a method of manufacturing a coated filament may include passing an electrically-conductive filament over a first roller electrode into a deposition chamber, withdrawing the coated filament from the deposition chamber over a second roller electrode, using the first roller electrode to establish direct electrical contact with the filament, using the second roller electrode to establish direct electrical contact with the coated filament to provide an electrical heating circuit through the filament, and passing at least one thermally-reactive gas into the deposition chamber to form the coating by chemical vapour deposition (CVD). Preferably leakage of the thermally-reactive gas past the roller electrodes is prevented.

Alternatively, a method of manufacturing a coated filament may include passing an electrically-conductive filament over a first roller electrode into a deposition chamber, withdrawing the coated filament from the deposition chamber over a second roller electrode, and using the first roller electrode to establish an electrostatic circuit to cause physical vapour deposition (PVD) of the coating from material within the deposition chamber.

### BRIEF DESCRIPTION OF THE DRAWINGS

The invention is now described, by way of example only, with reference to the accompanying drawings in which:

FIG. 1 is a diagrammatic side elevation of a known filament coating apparatus using chemical vapour deposition CVD,

FIG. 2 is an enlarged vertical cross-section, taken on the line 2-2 in FIG. 1, illustrating a known combined entrance electrode and entrance sealing means;

FIG. 3 is a diagram showing, in vertical section, one form of filament coating apparatus as taught by the present invention;

FIG. 4 is an enlarged vertical cross-section similar to FIG. 2 but illustrating the provision of an alternative roller electrode means as taught by the present invention, and

FIG. 5 is similar to FIG. 4 but illustrates the provision another form of roller electrode.

### DETAILED DESCRIPTION OF THE INVENTION

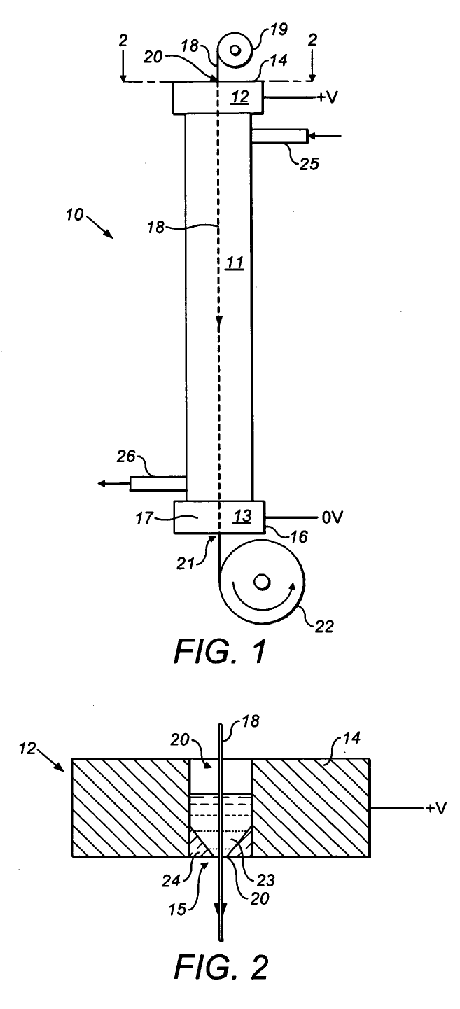

With reference to FIGS. 1 and 2, a known construction of filament coating apparatus is indicated generally by arrow 10 and consists of a long vertical tube 11 closed by end plates 12 and 13. The tube 11 is about 4 metres long and is made of borosilicate glass. The upper end plate 12 acts as an entrance electrode 14 and as a housing for an entrance sealing means 15 as shown in FIG. 2. The lower end plate 13 acts as an exit electrode 16 and as a housing for an exit sealing means 17 which is of identical construction to the entrance sealing means 15.

A suitable electrically-conducting filament 18, for instance a tungsten wire or a carbon fibre, is fed from a supply spool 19, through an entrance passage 20 in the entrance electrode 14 into the longitudinal tube 11, and progresses through an exit passage 21 in the exit electrode 16 to a storage spool 22. The supply spool 19 and the storage spool 22 form parts of an otherwise unshown spooling mechanism which continually moves the filament 18 at an appropriate speed through the tube 11.

With reference to FIG. 2, the entrance electrode 14 is made of metal or glass and defines the upper and lower ends of the entrance passage 20 which are separated by a small reservoir 23 containing a pool of about 0.5 cm³ of liquid mercury retained by surface tension in the much narrower lower end of the entrance passage 20, this has a diameter of typically 10-300 μm and is defined by a watchmaker's ruby 24. Instead of ruby, sapphire, ceramic or glass may be used but would need to be replaced more frequently. The pool of liquid mercury has a dual function in forming a sealing means that allows the filament 18 to slide through the entrance passage 20 whilst providing indirect electrical contact between the end plate 12 and the filament 18. Instead of using mercury, other low melting point eutectics have been used.

A potential difference of typically 4 KV is applied across the electrodes 14, 16 to their respective mercury contacts with the filament 18 thereby causing a current to flow through the filament 18 and its coating to create a desired temperature rise, typically to between 800° C. and 1500° C. Reactive gases are passed into the tube 11 through an inlet 25, and exit through an outlet 26. These gases react at, or near, the hot surface of the filament 18 and deposit a coating of which the thickness increases as the filament passes through the tube 11. The coating thickness of the coated filament where it enters the exit passage 21 is typically 5-10 times the diameter of the filament. For this reason, the diameter of the exit passage 21 is correspondingly larger than that of the entrance passage 20. Apart from having a larger exit passage 21, the configuration and operation of the exit electrode 16 is identical to that already described with reference to the entrance electrode 14.

The coated filament has a variety of uses dependant on the composition of the coating, for instance the fabrication of high performance metal-matrix composites.

The use of mercury has several disadvantages due to its toxicity. Operators of such known filament coating apparatus could come into physical contact with mercury vapour, and/or liquid mercury droplets, should they fail to follow appropriate health and safety guidelines. Some of the mercury is transferred to the surface of the filament and to the coated filament by the liquid mercury in the reservoirs 23, and any mercury leaking into the tube 11 may become incorporated in the filament coating and/or be entrained in the waste gas exiting through the gas outlet 26 thereby necessitating precautions in its disposal. Traces of mercury on or in the coated filament are a potential hazard to users of the coated filament and could also adversely affect the physical properties of the coating, its adherence to the filament, and particularly its adherence to the metal in a metal-matrix composite.

Attempts have been made to replace the mercury with a variety of low-melting point eutectic alloys, but these all incur the release of associated toxins and suffer from equivalent disadvantages.

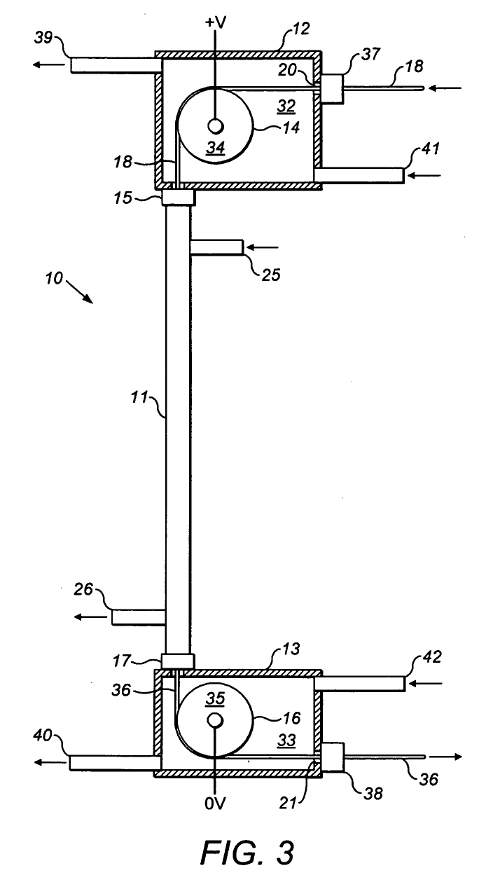

FIGS. 3, 4 and 5 use the same reference numerals as FIGS. 1 and 2 to denote equivalent elements which have the same function as already described. However the embodiments of FIGS. 3, 4 and 5 overcome the above-mentioned disadvantages by modifying the end plates 12, 13 to define electrode chambers 32 and 33 containing respective roller electrodes in the form of electrode wheels 34, 35 to achieve direct electrical contact with the filament 18 and the coated filament 36, without the use of mercury or any other low-melting point alloy.

With specific reference to FIG. 3, a potential difference +V−0V is applied across the electrode wheels 34, 35 to cause the heating current to flow along the filament 18 from its point of contact with the electrode wheel 34 to the point of contact between the electrode wheel 35 and the coated filament 36. The filament 18 enters the entrance passage 20 to the electrode chamber 32 via a sealing means 37 and leaves the electrode chamber 32 via the sealing means 15, whilst the coated filament 36 enters the electrode chamber 33 via the sealing means 17 and leaves the electrode chamber 33 via the exit passage 21 and a sealing means 38. The electrode chambers 32, 33 are preferably operated at a sub-atmospheric pressure applied through outlets 39, 40 with the sealing means 15, 17 acting as gas to vacuum seals and the sealing means 37 and 38 acting as air to vacuum seals. In this manner, the sealing means 15, 17 inhibit escape of the reactant gases from the tube 11 into the electrode chambers 32, 33 and the sealing means 37, 38 inhibit the entry of atmospheric air into the electrode chambers 32, 33. Any reactant gas and/or atmospheric air entering either of the electrode chambers 32, 33 will be sucked out through the respective outlet 39, 40 and can be fed through a suitable cleaner/neutraliser. Instead of operating the electrode chambers 32, 33 at a sub-atmospheric pressure, an innocuous gas for instance argon, or nitrogen, or some other gas appropriate to the coating process) may be supplied at a pressure slightly greater than that in the tube 11 via respective inlets 41 and 42. With either embodiment, the reactive gases within the tube 11 are isolated from the surrounding atmosphere.

The electrode wheels 34, 35 are positioned relative to their respective inlet and outlet passages 20, 21 and have a diameter selected so that the filament 18 or the coated filament 36 is in adequate direct electrical contact whilst not being damaged by the radius of curvature. In this manner, the filament 18 can enter horizontally and the coated filament 36 can exit horizontally, thereby minimising the height of the filament coating apparatus 10.

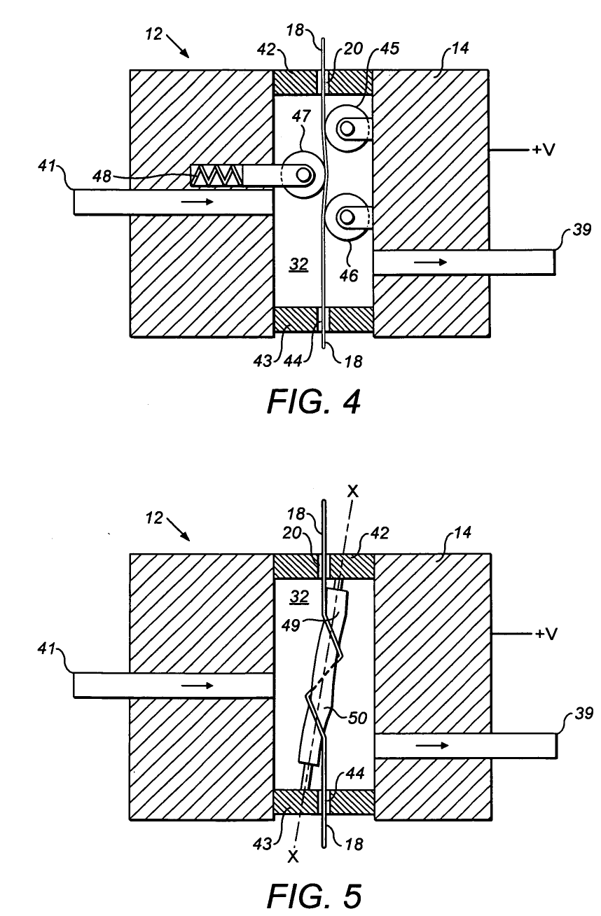

With specific reference to FIG. 4, the end plate 12 is modified so that the filament 18 enters the electrode chamber 32 through a first plate 42 defining the entrance passage 20, and leaves the electrode chamber 32 through a second plate 43 defining an exit passage 44. The passages 20, 44 have internal diameters that will provides a close sliding clearance for the filament 18 of which the diameter is typically 14 μm. To ensure good wear resistance, the plates 42, 43 are made out of ruby or sapphire, for instance jeweller's rubies or sapphires may be used, but could be made of ceramic or glass if more frequent replacement is acceptable. The roller electrode means 14 comprises three wheels 45, 46 and 47 positioned such that the wheels 45, 46 press against one side of the filament 11 whilst the third wheel 47 is opposed to the wheels 45, 46 and is pressed against the opposite side of the filament 18 by a compression spring 48 to provide even filament tension. As illustrated, the wheels 45, 46 and 47 are mounted for rotation from respective brackets carried by the end plate 14 to receive the potential +V. Provided the tension in the filament 18 is adequate to ensure adequate direct electrical contact, one of the wheels 46 or 47 may be omitted. It will be noted from the drawing that the filament 18 is deflected as it passes the wheels 45, 46 and 47 thereby ensuring excellent electrical contact with the filament 18. Good electrical contact is essential to avoid arcing. The degree of overlap between the wheels 45, 46 and 47 may be fixed for a filament 18 or coated filament 36 of particular diameter but may be variable to accommodate different diameters.

The electrode chamber 32 can be provided with an outlet 39 and an inlet 41 which can be operated as described with reference to FIG. 3.

The exit electrode 16 will be constructed in the same manner as the entrance electrode 14 as just described with reference to FIG. 4, the only point of difference being that the exit passage 21 in the lower end plate is essentially of greater diameter to permit the much larger diameter of the coated filament to slide through it.

With reference to FIG. 5, the roller electrode means 14 comprises a roller electrode 49 mounted for rotation about an axis X-X that, as shown, is oblique to a line between the entrance passage 20 and the exit passage 44. The filament is wound once around the roller electrode 49 to ensure adequate electrical contact. The roller electrode 49 is shaped to define a spiral surface 50 which engages the filament 18 and retains it in position whilst the electrode 49 rotates to ensure adequate direct electrical contact. Although the roller electrode is shown journaled from the plates 42 and 43, it could be mounted for rotation from other structure electrically connected to the entrance electrode 14.

The exit electrode 16 will again be constructed in the same manner as the entrance electrode 14 as just described with reference to FIG. 5, the only point of difference being that the exit passage 21 in the lower end plate 12 is essentially of greater diameter to permit the much larger diameter of the coated filament to slide through it.

If desired, the longitudinal tube 11 could be sufficiently large to process several filaments 18 using either single end plates 12, 13 serving respectively as entrance and exit electrodes 14, 16, or could carry a separate pair of electrodes for each filament.

The various roller electrodes 34, 35, 45, 46, 47 or 49 may have flat or grooved contact surfaces, and such grooves may be v-shaped or radiused. Further rollers or wheels may be provided to operate in one or more planes to align or otherwise control the path of the filament or of the coated filament.

The various roller electrodes 34, 35, 45, 46, 47 or 49 may be formed from metal or from an alternative conducting material. They may be designed to wear preferentially to the filament 18 or the coated filament 36, or be hard enough to withstand such wear.

To this point the description has related to apparatus for, and methods of, chemically depositing a coating on a filament 18. The apparatus and method can also be applied to the physical deposition of a coating on a filament, for instance by sputtering, electrostatic painting or vacuum deposition. In such cases the roller electrode means 14 and 16 can form part of an electrostatic circuit to produce an appropriate electrostatic charge on the filament.

Although various embodiments of the invention have been shown and described herein, they are not meant to be limiting. Those of skill in the art may recognize certain modifications to these embodiments, which modifications are meant to be covered by the spirit and scope of the appended claims.

What is claimed is:

1. Filament coating apparatus comprising:
a deposition chamber in which a coating is to be applied to a filament;
a first electrode chamber having:
an entrance passage permitting said filament to slide into said first electrode chamber;
an exit passage permitting said filament to slide from said first electrode chamber into said deposition chamber;
a second electrode chamber having:
an entrance passage permitting said coated filament to slide out of said deposition chamber into said second electrode chamber;
an exit passage permitting said coated filament to slide out of said second electrode chamber;
said first electrode chamber housing a first roller electrode means providing direct electrical contact with said filament; and
said second electrode chamber housing a second roller electrode means providing direct electrical contact with said coated filament.

2. Filament coating apparatus, as in claim 1, having sealing means to inhibit the escape of gas from said deposition chamber into either of said electrode chambers.

3. Filament coating apparatus, as in claim 2, having a gas inlet to supply gas to each of said electrode chambers at a pressure greater than an operational pressure within said deposition chamber.

4. Filament coating apparatus, as in claim 2, in which each of said electrode chambers has a gas outlet to reduce gas pressure within said electrode chambers to below ambient atmospheric pressure.

5. Filament coating apparatus, as in claim 2, in which each of said sealing means comprises a gas outlet for any gas escaping from said deposition chamber into said electrode chamber.

6. Filament coating apparatus comprising:
a deposition chamber in which a coating is to be applied to a filament;
a first electrode chamber having:
an entrance passage permitting said filament to slide into said first electrode chamber; and
an exit passage permitting said filament to slide from said first electrode chamber into said deposition chamber;
a second electrode chamber having:
an entrance passage permitting said coated filament to slide out of said deposition chamber into said second electrode chamber; and
an exit passage permitting said coated filament to slide out of said second electrode chamber;
said first electrode chamber housing a first electrode wheel positioned relative to its said entrance passage and its said exit passage to ensure direct electrical contact said filament; and
said second electrode chamber housing a second electrode wheel positioned relative to its said entrance passage and its said exit passage to ensure direct electrical contact with said coated filament.

7. Filament coating apparatus, as in claim 6, in which said entrance passage to the first electrode chamber and said exit passage from the second electrode chamber are both horizontal.

8. Filament coating apparatus comprising:
a deposition chamber in which a coating is to be applied to a filament;
a first electrode chamber having:
an entrance passage permitting said filament to slide into said first electrode chamber; and
an exit passage permitting said filament to slide from said electrode chamber into said deposition chamber;
a second electrode chamber having:
an entrance passage permitting said coated filament to slide out of said deposition chamber into said second electrode chamber; and
an exit passage permitting said coated filament to slide out of said second electrode chamber;
said first electrode chamber housing at least two electrode wheels positioned to engage opposite sides of the filament to ensure direct electrical contact with the filament; and
said second electrode chamber housing at least two further electrode wheels positioned to engage opposite sides of the coated filament to ensure direct electrical contact with the coated filament.

9. Filament coating apparatus, as in claim 8, in which said first electrode chamber houses three of said electrode wheels positioned such that two of said electrode wheels are pressed against one side of said filament and the third of said electrode wheels is pressed against the opposite side of said filament in a position between the said two electrode wheels.

10. Filament coating apparatus, as in claim 8, in which said second electrode chamber houses three of said electrode wheels positioned such that two of said electrode wheels are pressed against one side of said coated filament and the third of said electrode wheels is pressed against the opposite side of said coated filament in a position between the said two electrode wheels.

11. Filament coating apparatus, as in claim 8, in which at least some of said electrode wheels are positioned to guide said filament into alignment with said exit passage from said first electrode chamber and to guide said coated filament into alignment with said exit passage from said second electrode chamber.

12. Filament coating apparatus comprising:
a deposition chamber in which a coating is to be applied to a filament;
a first electrode chamber having:
an entrance passage permitting said filament to slide into said first electrode chamber; and
an exit passage permitting said filament to slide from said first electrode chamber into said deposition chamber;
a second electrode chamber having:
an entrance passage permitting said coated filament to slide out of said deposition chamber into said second electrode chamber; and
an exit passage permitting said coated filament to slide out of said second electrode chamber; and
said first electrode chamber housing a roller electrode mounted for rotation about an axis oblique to a line between the entrance passage to said first electrode chamber and the exit passage from said first electrode chamber whereby said filament can be wound around said roller electrode to ensure adequate direct electrical contact.

13. Filament coating apparatus, as in claim 12, in which the roller electrode has a spiral surface for engaging the filament.

14. Filament coating apparatus, as in claim 12, in which said second electrode chamber houses a second roller electrode mounted for rotation about an axis oblique to a line between the entrance passage to said second electrode chamber and the exit passage from said second electrode chamber whereby said coated filament can be wound around said second roller electrode to ensure adequate direct electrical contact.

15. Filament coating apparatus, as in claim 14, in which said second roller electrode has a spiral surface for engaging the coated filament.

16. A method of coating a filament including:
passing an electrically-conductive filament over a first roller electrode into a deposition chamber;
withdrawing the coated filament from said deposition chamber over a second roller electrode;
using said first roller electrode to establish direct electrical contact with said filament;
using said second roller electrode to establish direct electrical contact with said coated filament to provide an electrical heating circuit through the filament; and
passing at least one thermally-reactive gas into said deposition chamber to form the coating by chemical vapour deposition.

17. A method of coating a filament including:
passing an electrically-conductive filament over a first roller electrode;
withdrawing the coated filament from said deposition chamber over a second roller electrode; and
using the first roller electrode to establish an electrostatic circuit to cause physical vapour deposition of the coating from material within the said deposition chamber.
